(19) United States
(12) Patent Application Publication
(10) Pub. No.: US 2012/0195443 A1
(43) Pub. Date: Aug. 2, 2012

(54) METHOD AND APPARATUS FOR OUTPUTTING AUDIO SIGNAL

(75) Inventors: Han-ki KIM, Suwon-si (KR); Hae-kwang PARK, Suwon-si (KR)

(73) Assignee: SAMSUNG ELECTRONICS CO., LTD., Suwon-si (KR)

(21) Appl. No.: 13/313,813

(22) Filed: Dec. 7, 2011

(30) Foreign Application Priority Data
Jan. 31, 2011 (KR) 10-2011-0009495

(51) Int. Cl. H03G 3/00

(52) U.S. Cl. 381/107

(57) ABSTRACT

An audio signal output apparatus including an audio signal input unit which receives an audio signal; a digital signal processor (DSP) which estimates an output power corresponding to the received audio signal, and adjusts at least one of a gain value to be applied to the received audio signal and the output power of the received audio signal according to a period for which the estimated output power exceeds a rated maximum output power and a difference between the estimated output power and the rated maximum output power; and an audio signal output unit which generates, amplifies, and outputs a pulse width modulation (PWM) signal corresponding to the received audio signal.

### CROSS-REFERENCE TO RELATED PATENT APPLICATION

This application claims priority from Korean Patent Application No. 10-2011-0009495, filed on Jan. 31, 2011, in the Korean Intellectual Property Office, the disclosure of which is incorporated herein in its entirety by reference.

### BACKGROUND

1. Field

Aspects of the exemplary embodiments of the present disclosure relate to a method and apparatus for outputting an audio signal, and more particularly, to a method and apparatus for outputting an audio signal with guaranteed maximum output power for improved reliability, and to a method and apparatus for outputting an audio signal with guaranteed maximum output power and improved sound quality.

2. Description of the Related Art

Audio power amps for receiving audio signals and outputting audible signals therefrom are categorized into classes A, B, AB, and D. Also, class D power amps are widely used due to their reduced deterioration of amplification efficiency as compared to classes A, B, and AB power amps. A class D power amp switches an audio signal by converting the audio signal into a pulse width modulation (PWM) signal. Class D power amps are also referred to as digital amps.

Digital amps are widely used due to having features of low data conversion loss and 100% amplification efficiency.

In such digital amps, it is important to output an input audio signal without generating signal distortion according to the maximum output power.

### SUMMARY

An aspect of the present disclosure provides a method and apparatus for outputting an audio signal, which is capable of preventing an operation exceeding the maximum output power.

An aspect of the present disclosure also provides a method and apparatus for outputting an audio signal, which is capable of minimizing the deterioration in sound quality that may occur during the adjustment of the maximum output power.

According to an exemplary embodiment, there is provided an audio signal output apparatus including an audio signal input unit, which receives input of at least one audio signal; a digital signal processor (DSP), which estimates an output power corresponding to the input audio signal and adjusts at least one of a gain value to be applied to the input audio signal and the output power of the input audio signal according to a period for which the estimated output power exceeds the rated maximum output power and a difference between the estimated output power and the rated maximum output power; and an audio signal output unit, which generates, amplifies, and outputs a pulse width modulation (PWM) signal corresponding to the input audio signal.

The DSP may adjust the gain value according to the period and the difference, such that the output power of the input audio signal is adjusted according to the rated maximum output power.

The gain value may decrease gradually or linearly during a period for which the estimated output power exceeds the rated maximum output power.

The DSP may adjust the output power of the input audio signal according to the period and the difference, such that the output power of the input audio signal is below or equal to the rated maximum output power of the audio signal output unit.

The audio signal output unit may include a PWM unit, which generates the PWM signal by modulating the pulse width of the input audio signal; a switching power unit, which generates an amplified PWM signal by amplifying the power of the PWM signal; and a speaker, which converts the amplified PWM signal into an audible signal and outputs the audible signal.

The DSP may adjust the output power of the speaker according to the period and the difference, such that the output power of the speaker is below or equal to the rated maximum output power of the speaker.

The DSP may adjust the output power of the speaker in the low frequency domain, such that the output power of the speaker is below or equal to the rated maximum output power of the speaker.

The DSP may perform an excursion control for lowering the overall output power of the speaker, such that the output power of the speaker is below or equal to the rated maximum output power of the speaker.

The audio signal output apparatus may further include a volume adjusting unit.

The DSP may estimate the output power of the audio signal by multiplying a maximum recording level, an audio volume level, and an overall gain value of the audio signal.

According to another exemplary embodiment, there is provided a method of outputting an audio signal, the method including receiving input of at least one audio signal; estimating an output power corresponding to the input audio signal; adjusting at least one of a gain value to be applied to the input audio signal and the output power of the input audio signal according to a period for which the estimated output power exceeds the rated maximum output power and a difference between the estimated output power and the rated maximum output power; and generating, amplifying, and outputting a pulse width modulation (PWM) signal corresponding to the input audio signal.

### BRIEF DESCRIPTION OF THE DRAWINGS

The above and/or other aspects of the present disclosure will be more apparent by describing certain exemplary embodiments with reference to the accompanying drawings, in which:

FIG. 1 is a block diagram of an audio signal output apparatus according to an exemplary embodiment;

FIG. 2 is a diagram showing an audio signal output apparatus according to an exemplary embodiment in closer detail;

FIG. 3 is a block diagram showing a DSP according to another exemplary embodiment in closer detail;

FIG. 4 is a graph illustrating an estimated output power and an output power limit of an audio signal output apparatus;

FIG. 5 is a graph illustrating an operation of a DSP for adjusting a gain value;

FIG. 6 is a graph illustrating an output audio signal that is output after a gain value adjusted by a DSP is applied thereto;

FIG. 7 is a block diagram showing a DSP according to another exemplary embodiment in closer detail;

FIG. 8 is a graph illustrating an operation of a DSP for adjusting output power;

FIG. 9 is another graph illustrating an operation of a DSP for adjusting output power;

FIG. 10 is a block diagram showing a DSP according to another exemplary embodiment in closer detail; and

FIG. 11 is a flowchart showing a method of outputting an audio signal, according to an exemplary embodiment.

### DETAILED DESCRIPTION OF THE EXEMPLARY EMBODIMENTS

Hereinafter, a method and apparatus for outputting an audio signal according to exemplary embodiments will be described in detail with reference to the attached drawings. However, the present disclosure is not restricted or limited to such exemplary embodiments. For reference, in explaining the present disclosure, well-known functions or constructions will not be described in detail so as to avoid obscuring the description with unnecessary detail.

An audio signal output apparatus for reproducing an audio signal by using a digital amp features the maximum output power that may be generated by an internally arranged amplifier (AMP). For example, an audio signal output apparatus may feature the maximum output power of 150 W/4 ohm per channel. Such maximum output power denotes the ideal maximum output power, and an amplification level of an input audio signal is determined according to the maximum output power.

Furthermore, the maximum output power may be designed by using an average recording level as a reference level. Furthermore, as an exception, an audio signal recorded at a level higher than the reference level may be input. If an audio signal recorded at a level higher than the reference level is reproduced, an audio signal output apparatus operates above the maximum output power. Such an operation inflicts damage to internal components of audio signal output apparatuses, such as digital amps, speakers, switching mode power supplies (SMPS), or the like. For example, no sound may be reproduced as a speaker may be burnt or blown. In the case of SMPS or a digital amp, circuit may be damaged due to increased temperature thereof.

To prevent the operation of an audio signal output apparatus above the maximum output power, output gain may be controlled. However, artificial control of the output gain of the audio signal in a period above the maximum output power may cause distortion of an audio signal. Such a distortion of an audio signal causes deterioration in sound quality.

Therefore, a method and apparatus for outputting an audio signal capable of controlling an output gain with minimized signal distortion will be described below in detail.

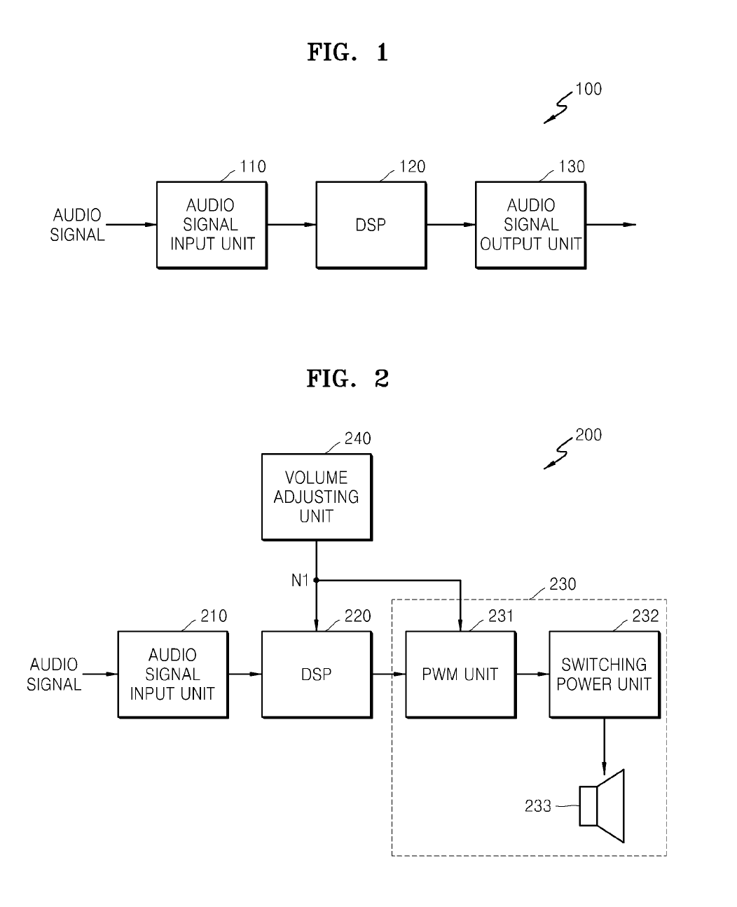

FIG. 1 is a block diagram of an audio signal output apparatus 100 according to an embodiment.

Referring to FIG. 1, the audio signal output apparatus 100 includes an audio signal input unit 110, a digital signal processor (DSP) 120, and an audio signal output unit 130.

The audio signal input unit 110 receives input of at least one audio signal.

The DSP 120 estimates output power of a final output audio signal in correspondence to the input audio signal. Next, at least one of a gain value to be applied to the audio signal and the output power of the audio signal is adjusted according to a period for which the estimated output power exceeds the rated maximum output power and a difference between the estimated output power and the rated maximum output power. Furthermore, the DSP 120 may digitally process the input audio signal by applying at least one of an adjusted gain value and an adjusted output power of the audio signal.

The audio signal output unit 130 generates, amplifies, and outputs a pulse width modulation (PWM) signal corresponding to an audio signal input by the DSP 120. In detail, the audio signal output unit 130 generates a PWM signal by modulating the pulse width of an audio signal that was digitally processed by applying at least one of an adjusted gain value and an adjusted output power of the audio signal.

Alternatively, the audio signal output unit 130 may modulate the pulse width of an input audio signal according to the gain value and/or the output power of the audio signal adjusted by the DSP 120. In detail, if the DSP 120 has digitally processed an input audio signal without applying the adjusted gain value and/or the adjusted output power of the audio signal, the audio signal output unit 130 may modulate the pulse width of the input audio signal according to the adjusted gain value and/or the adjusted output power of the audio signal and output a PWM signal.

For example, an audio signal with an adjusted gain may be generated by applying a predetermined gain value to an input audio signal according to the control of the DSP 120, and a PWM signal may be generated by modulating the pulse width of the audio signal with an adjusted gain. Here, the predetermined gain value may be a gain value adjusted by the DSP 120. Next, an amplified PWM signal may be generated by increasing the amplitude of the PWM signal. Furthermore, in terms of generating an amplified PWM signal, the audio signal output unit 130 may adjust the output power of an audio signal adjusted by the DSP 120. In other words, the PWM signal is amplified so as not to exceed the output power of an adjusted audio signal.

An audio signal output apparatus according to an exemplary embodiment will be described below in detail with reference to FIG. 2.

FIG. 2 is a diagram showing an audio signal output apparatus 200 according to an exemplary embodiment. An audio signal input unit 210, a DSP 220, and an audio signal output unit 230 of FIG. 2 correspond to the audio signal input unit 110, the DSP 120, and the audio signal output unit 130 of FIG. 1, respectively. Compared to the audio signal output apparatus 100 of FIG. 1, the audio signal output apparatus 200 may further include a volume adjusting unit 240. Furthermore, the audio signal output unit 230 may include a PWM unit 231, a switching power unit 232, and a speaker 233.

The audio signal input unit 210 receives input of at least one audio signal. In detail, the audio signal input unit 210 may receive input of an audio signal from each of a plurality of channels. An input audio signal may be an analog signal or a digital signal.

The volume adjusting unit 240 may include a user interface (UI) unit (not shown) for receiving a request of a user for volume adjustment or informing the progress of volume adjustment. The volume adjusting unit 240 sets a corresponding audio signal level in response to a request of a user for volume adjustment. Next, the volume adjusting unit 240 transmits audio volume level information to the DSP 220 and the audio signal output unit 230.

The PWM unit 231 generates a PWM signal corresponding to an input audio signal. In detail, the PWM unit 231 receives input of an audio signal output by the DSP 220 and generates a PWM signal by modulating the pulse width of the input audio signal.

Alternatively, the PWM unit 231 may compress, decompress, or boost an input audio signal by using a gain value adjusted by the DSP 220. Next, the PWM unit 231 may output a PWM signal by modulating the pulse width of the compressed, decompressed, or boosted audio signal.

The switching power unit 232 generates an amplified PWM signal by amplifying the power of a PWM signal. In detail, the switching power unit 232 may amplify the amplitude of a PWM signal according to the rated maximum output power of the audio signal output apparatus 200 and output the amplified PWM signal.

The speaker 233 receives input of a PWM signal amplified by the switching power unit 232, converts the PWM signal into an audio signal that is audible by a user, and outputs the audio signal. The speaker 233 may have a rated maximum output power of its own, separately from the switching power unit 232.

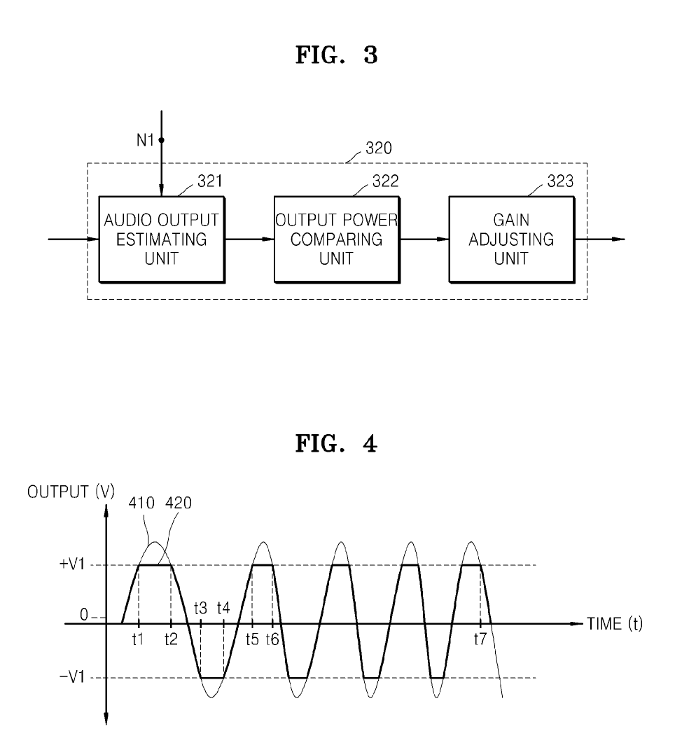

Hereinafter, the configuration and operation of the DSP 220 will be described in detail with reference to FIGS. 3 through 10.

The DSP 220 estimates the output power corresponding to an input audio signal. Next, the DSP 220 adjusts at least one of a gain value to be applied to the audio signal and the output power of the audio signal based on a period for which the estimated output power exceeds the rated maximum output power and a difference between the estimated output power and the rated maximum output power.

In detail, the DSP 220 determines the maximum recording level of an audio signal input via the audio signal input unit 210. For example, the average signal level or the highest value from among the peak signal levels of at least one audio signal input during a processing period or sampling period of the DSP 220 may be determined as the maximum recording level. Here, the processing period of the DSP 220 may vary according to the product specifications or models of the audio signal output apparatus 200. For example, the processing period of the DSP 220 may be 5.3 msec, 10.6 msec, etc.

Furthermore, the DSP 220 receives currently set audio volume level information from the volume adjusting unit 240.

Next, the overall gain value of the input audio signal output apparatus 200 may be calculated. Here, the overall gain value may be a gain value obtained by comparing an audio signal input to the audio signal output apparatus 200 with a final audio signal output by the audio signal output apparatus 200.

The DSP 220 may estimate the output power of an input audio signal by using the audio volume level, overall gain value, and determined maximum recording level of the audio signal. The estimated output power of an input audio signal may be a value obtained by multiplying a maximum recording level, an audio volume level, and an overall gain value of the audio signal. In other words, the estimated output power may be expressed as: estimated output power=maximum recording level×audio volume level×overall gain value.

FIG. 3 is a block diagram showing a DSP 320 according to another exemplary embodiment.

Referring to FIG. 3, the DSP 320 corresponds to the DSP 120 of FIG. 1 or the DSP 220 of FIG. 2. The DSP 320 may include an audio output estimating unit 321, an output power comparing unit 322, and a gain adjusting unit 323.

The audio output estimating unit 321 receives the audio volume level from the volume adjusting unit 240, determines the overall gain value and the maximum recording level, and calculates the estimated output power.

The output power comparing unit 322 compares the estimated output power and the rated maximum output power, determines a period of time for which the estimated output power exceeds the rated maximum output power, and determines a difference between the estimated output power and the rated maximum output power. Next, the output power comparing unit 322 transmits the determined period and the determined difference to the gain adjusting unit 323.

The gain adjusting unit 323 adjusts a gain value to be applied to an input audio signal based on the determined period for which the estimated output value exceeds the rated maximum output power and the determined difference between the estimated output value and the rated maximum output power, which are transmitted from the output power comparing unit 322. The gain value adjusted herein may be the overall gain value of the audio signal output apparatus 200 or a gain value of the audio signal output unit 230.

Hereinafter, operation of the DSP 320 will be described in detail with reference to FIGS. 4 through 6.

FIG. 4 is a graph illustrating an estimated output power and an output power limit of an audio signal output apparatus.

Referring to FIG. 4, an output power 410 estimated by the audio output estimating unit 321 is exemplified. The X-axis denotes time, whereas the Y-axis denotes output power corresponding to an input audio signal in volts. Furthermore, the voltage +V1 denotes the positive rated maximum output power of the audio signal output apparatus 100, whereas the voltage −V1 denotes the negative rated maximum output power of the audio signal output apparatus 100. Furthermore, the rated maximum output power may be the output power of a power source of an amp included in the audio signal output apparatus 100. Furthermore, the amp may be arranged in the switching power unit 232.

A case in which the estimated output power 410 exceeds the rated maximum output power during periods between t1 and t7 is shown as an example. When an output power corresponding to an input audio signal exceeds the rated maximum output power, the rated maximum output power is output instead of the output power corresponding to the input audio signal during the corresponding period, e.g., a period between t1 and t2. For example, all output powers exceeding the voltage +V1 are clipped, and an input audio signal is finally output as indicated by a graph 420. In detail, clippings occur in periods between t1 and t2, between t3 and t4, and between t5 and t6.

When an input audio signal is clipped and finally output, the audio signal is distorted, and thus, sound quality deteriorates. Therefore, according to at least one of the exemplary embodiments, the gain value adjustment, as described above with reference to FIG. 3, is performed to prevent clipping and deterioration in sound quality as described above with reference to FIG. 4.

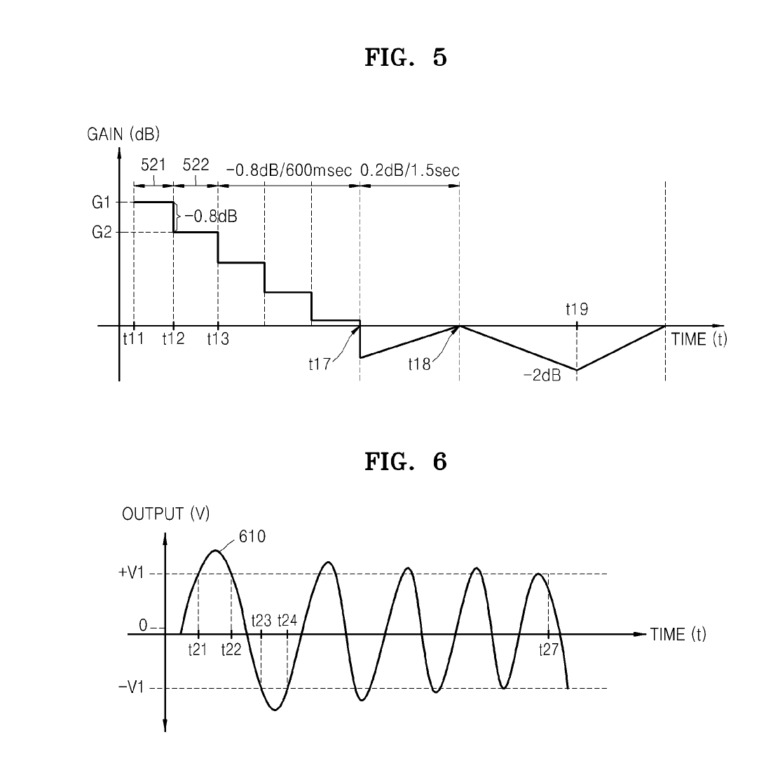

FIG. 5 is a graph illustrating an operation of a DSP for adjusting a gain value. In FIG. 5, the X-axis denotes time, whereas the Y-axis denotes gain values in decibels (dB).

The DSP 320, more particularly, the gain adjusting unit 323 may adjust a gain value to be applied to an input audio signal to decrease gradually or linearly during a period for which an estimated output power exceeds the rated maximum output power.

FIG. 5 illustrates a case in which the gain adjusting unit 323 gradually reduces a gain value applied to an audio signal during periods between t11 and t17 during which an estimated output power exceeds the rated maximum output power. The time points t11 through t17 of FIG. 5 correspond to the time points t1 through t7 of FIG. 4, respectively.

Referring to FIG. 5, a gain value may continuously be a previous gain value G1 for preventing rapid change and distortion of an audio signal due to rapid adjustment of a gain value during the first period between t11 and t12 from among the periods between t11 and t17 during which an estimated output power exceeds the rated maximum output power. Furthermore, throughout the periods between t11 and t17, a gain value may be reduced gradually or linearly to prevent rapid change and distortion of an audio signal.

In detail, in the periods between t11 and t17 during which an estimated output power exceeds the rated maximum output power, the gain value G1 is applied during a first period 521 between t11 and t12, whereas a gain value G2, which is a gain value reduced from the gain value G1 by 0.8 dB, is applied during a second period 522 between t12 and t13. Each of the first period 521 and the second period 522 may be 600 msec, and a gain value may be gradually reduced during periods between t13 and t17 at a rate of −0.8 dB/600 msec.

A gain value to be applied to an input audio signal and a rate of reducing the gain value may be determined based on a period for which the estimated output power exceeds the rated maximum output power and based on a difference between the estimated output power and the rated maximum output power. Furthermore, a specific gain value and a specific rate of reducing the gain value may vary according to product specifications or models of the audio signal output apparatus 100, such as rated maximum output power, performance of an amp, etc. Therefore, the gain value and the rate of reducing the gain value may be optimized by a manufacturer of an audio signal output apparatus, a user of the audio signal output apparatus, or an audio signal output apparatus in consideration of product specifications of the audio signal output apparatus.

FIG. 6 is a graph illustrating an output audio signal that is output after a gain value adjusted by a DSP is applied thereto.

Referring to FIG. 6, an audio signal 610 to which an adjusted gain value as described above with reference to FIG. 5 is applied is exemplified. The time points t21 through t27 of FIG. 6 correspond to the time points t1 through t7 of FIG. 4.

In the case where an audio output power temporarily exceeds the maximum output power, the audio signal output apparatus 100 is not damaged. Furthermore, to improve dynamic performance of the audio signal output apparatus 100, it is necessary to maintain the output power of the input audio signal to temporarily exceed the rated maximum output power. Therefore, as described above with reference to FIG. 5, a gain value is not reduced during a first period between t11 and t12, and thus, the audio signal 610 may be temporarily output above the rated maximum output power during the period between t21 and t22 of FIG. 6.

Furthermore, by gradually reducing a gain value and applying the reduced gain value to the input audio signal as described above with reference to FIG. 5, periods during which an output power exceeds the rated maximum output power, e.g., a period between t23 and t24, may be gradually reduced, and thus, an audio signal may be output at the rated maximum output power at the time point t27.

Furthermore, referring to FIG. 5, the DSP 120 may perform additional gain value adjustment after the time point t17, which is a time point after an audio signal is output at the rated maximum output power. For example, a dynamic range of an audio signal may be increased by linearly increasing a gain value during a period between t17 and t18 and the gain value may be reduced by 2 dB during a period between t18 and 19 so as not to output the audio signal above the rated maximum output power.

As described above with reference to FIGS. 4 and 5, output power of an input audio signal may be adjusted according to the rated maximum output power of the audio signal output apparatus 100 with minimized distortion of the input audio signal, by performing anti-distortion control for gradually or linearly reducing a gain value to be applied to the input audio signal, in consideration of a period during which an estimated output power exceeds the rated maximum output power and a difference between the estimated output power and the rated maximum output power.

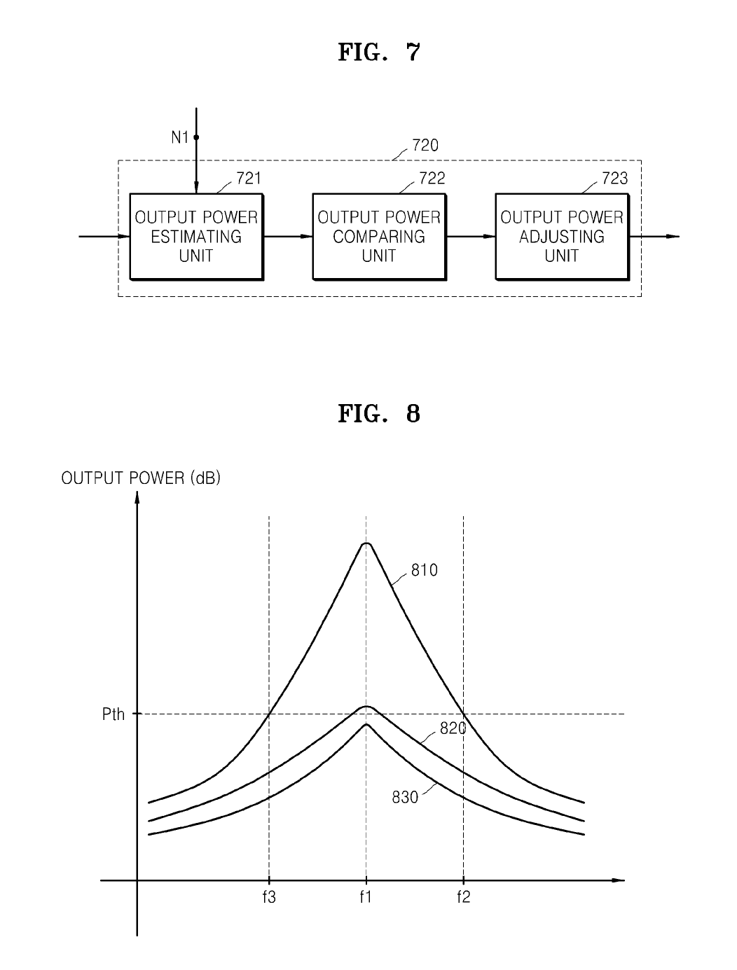

FIG. 7 is a block diagram showing a DSP 720 according to another exemplary embodiment.

The DSP 720 may adjust a final output power of an audio signal, such that the final output power is less than or equal to the rated maximum output power of an audio signal output unit according to a period during which an estimated output power of the input audio signal exceeds the rated maximum output power and a difference between the estimated output power and the rated maximum output power.

The DSP 720 of FIG. 7 corresponds to the DSP 120 of FIG. 1 or the DSP 220 of FIG. 2. The DSP 720 may include an output power estimating unit 721, an output power comparing unit 722, and an output power adjusting unit 723.

The output power estimating unit 721 estimates the output power of a final audio signal output by the audio signal output unit 230. In detail, the output power estimating unit 721 estimates output power of a final audio signal output by the speaker 233. The estimation of output power may be identical to the estimation of output power performed by the audio output estimating unit 321 of FIG. 3. Here, the output power of a final audio signal output by the speaker 233 is estimated in consideration of the rated maximum output power of the speaker 233.

The output power comparing unit 722 compares the rated maximum output power of the speaker 233 and an output power estimated by the output power estimating unit 721, determines a period for which the estimated output power exceeds the rated maximum output power, and determines a difference between the estimated output power and the rated maximum output power. The determined period for which the estimated output power exceeds the rated maximum output power and the determined difference between the estimated output power and the rated maximum output power, determined by the output power comparing unit 722, are identical to the period for which the estimated output power exceeds the rated maximum output power and the difference between the estimated output power and the rated maximum output power determined by the output power comparing unit 322, and thus, detailed descriptions thereof will be omitted.

The output power adjusting unit 723 adjusts the output power of the speaker 233, such that the output power of the speaker 233 corresponding to an input signal is below or equal to the rated maximum output power of the speaker 233 according to the period for which the estimated output power exceeds the rated maximum output power and the difference between the estimated output power and the rated maximum output power that are determined by the output power comparing unit 722. In detail, the output power adjusting unit 723 may adjust the output power of the speaker 233 by adjusting a gain value to be applied to an audio signal by the speaker 233.

FIG. 8 is a graph illustrating an operation of a DSP 720 for adjusting output power.

Referring to FIG. 8, the X-axis denotes frequencies, whereas the Y-axis denotes output powers of the speaker 233 in dB. A graph 810 indicates an example of output powers of the speaker 233 estimated by the output power estimating unit 721. The rated maximum output power of the speaker 233 is indicated as Pth.

The output power adjusting unit 723 may lower the output power of the speaker 233 to or below the rated maximum output power Pth in a frequency band between f3 and f2 in which the estimated output power of the speaker 233 exceeds the rated maximum output power Pth while maintaining the shape of the output power corresponding to an audio signal, as indicated by the graph 810. For example, as shown in FIG. 8, the output power adjusting unit 723 may perform excursion control for lowering overall output power of the speaker 233, such that the output power of the speaker 233 has a shape as indicated by a graph 820 or a graph 830. Therefore, at the center frequency f1, the maximum output power may be obtained and the shape of the output power may have the same shape as the output power of the speaker 233 prior to adjustment as indicated by the graph 810.

Therefore, according to the exemplary embodiment, distortion of an audio signal due to output power adjustment may be minimized by minimizing the change of a shape of audio signal.

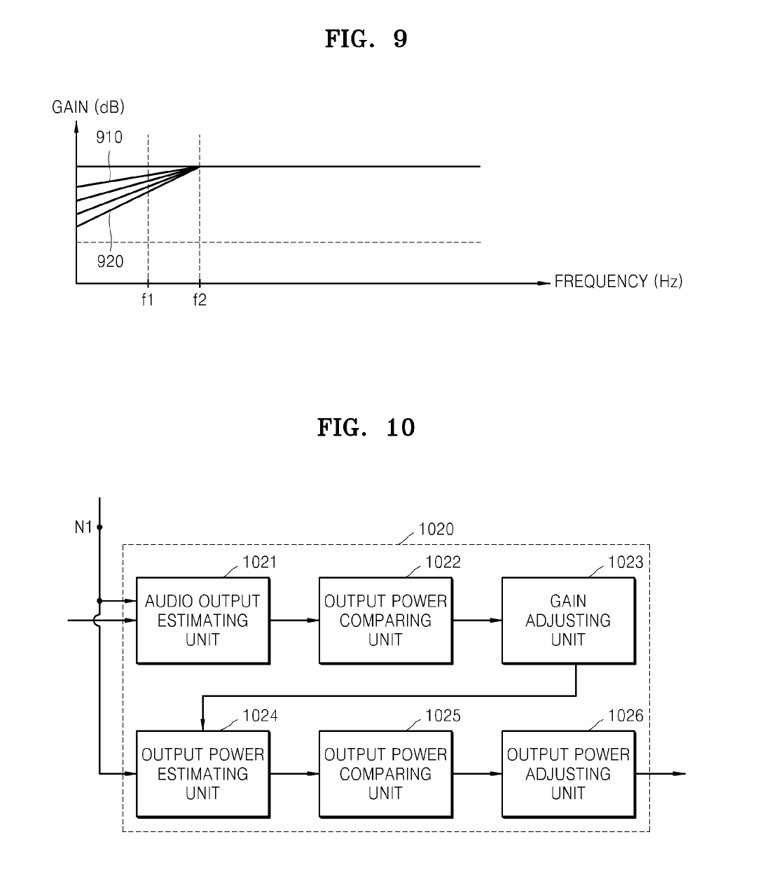

FIG. 9 is another graph illustrating an operation of a DSP 720 for adjusting output power.

Referring to FIG. 9, gain values applied to the speaker 233 are shown. The X-axis denotes frequencies, whereas the Y-axis denotes gain values applied to the speaker 233.

Referring to FIG. 9, to lower the output power of the speaker 233, a gain value of the speaker 233 may be adjusted in a frequency band between f3 and f2 during which the estimated output power of the speaker 233 exceeds the rated maximum output power Pth of the speaker 233.

As a difference between the estimated output power of the speaker 233 and the rated maximum output power Pth of the speaker 233 increases, a rate of reducing a gain value may increase. In other words, a gain value may be rapidly reduced as indicated by a graph 910 in the case where a difference between the estimated output power of the speaker 233 and the rated maximum output power Pth of the speaker 233 is large, whereas a gain value may be slowly reduced as indicated by a graph 920 in the case where a difference between the estimated output power of the speaker 233 and the rated maximum output power Pth of the speaker 233 is small.

Furthermore, the speaker 233 has an output frequency limited according to the output power of the speaker 233. Particularly, an operation of a satellite speaker is restricted in the low frequency domain. Generally, high power output in the low frequency domain may damage a speaker. Therefore, the output power adjusting unit 723 may adjust output power in the low frequency domain.

In detail, the output power adjusting unit 723 may perform excursion control for lowering overall output power of the speaker 233, such that the output power of the speaker 233 is below or equal to the rated maximum output power of the speaker 233.

FIG. 10 is a block diagram showing a DSP 1020 according to another exemplary embodiment.

The DSP 1020 of FIG. 10 corresponds to the DSP 120 of FIG. 1 or the DSP 220 of FIG. 2. The DSP 1020 may include an audio output estimating unit 1021, an output power comparing unit 1022, a gain adjusting unit 1023, an output power estimating unit 1024, an output power comparing unit 1025, and an output power adjusting unit 1026.

Here, the audio output estimating unit 1021, the output power comparing unit 1022, and the gain adjusting unit 1023 respectively correspond to the audio output estimating unit 321, the output power comparing unit 322, and the gain adjusting unit 323 described above with reference to FIG. 3, and thus, detailed descriptions thereof will be omitted. Furthermore, the output power estimating unit 1024, the output power comparing unit 1025, and the output power adjusting unit 1026 respectively correspond to the output power estimating unit 721, the output power comparing unit 722, and the output power adjusting unit 723 of FIG. 7, and thus, detailed descriptions thereof will be omitted.

Referring to FIG. 10, the DSP 1020 may perform anti-distortion control for adjusting a gain value to be applied to an audio signal via the audio output estimating unit 1021, the output power comparing unit 1022, and the gain adjusting unit 1023, and may thereafter perform an excursion control for adjusting the output power of a speaker corresponding to an input audio signal via the output power estimating unit 1024, the output power comparing unit 1025, and the output power adjusting unit 1026.

As described above, an audio signal output apparatus according to exemplary embodiments may prevent itself from operating above the maximum output power, and thus, the audio signal output apparatus may prevent itself from being damaged. As a result, the reliability of the audio signal output apparatus may be improved.

Furthermore, a change of an output shape of an audio signal, which may occur during the adjustment of the maximum output power, may be minimized, and thus, distortion of an audio signal due to the adjustment of output power may be minimized. Therefore, deterioration in sound quality may be minimized.

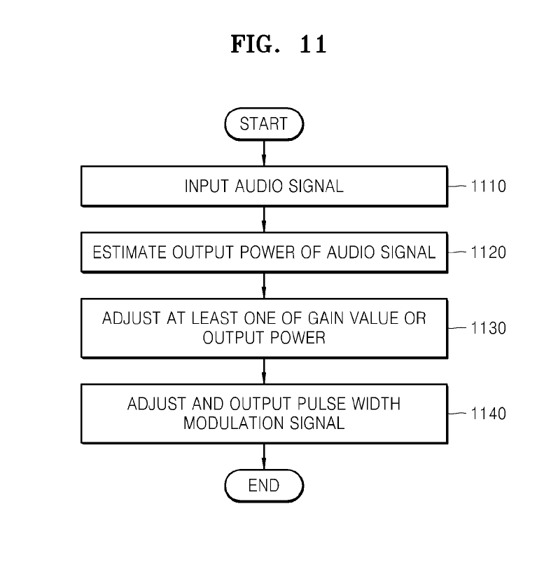

FIG. 11 is a flowchart showing a method of outputting an audio signal, according to an exemplary embodiment. Hereinafter, the method of outputting an audio signal will be described with reference to each of the components of the audio signal output apparatus 100 shown in FIG. 1.

Referring to FIG. 11, according to the method of outputting an audio signal, input of at least one audio signal is received (operation 1110). The operation 1110 may be performed by the audio signal input unit 110.

The output power corresponding to the input audio signal is estimated (operation 1120). The operation 1120 may be performed by the DSP 120.

Based on a period for which the estimated output power exceeds the rated maximum output power and a difference between the estimated output power and the rated maximum output power, at least one of a gain value to be applied to the audio signal and the output power of the input audio signal is adjusted (operation 1130). Operation 1130 may be performed by the DSP 120.

Next, a PWM signal corresponding to the input audio signal is generated, amplified, and output (operation 1140). Operation 1140 may be performed by the audio signal output unit 130.

The technical spirit and configurations of operations of the method of outputting an audio signal, according to the exemplary embodiment, as described above, are identical to those of an audio signal output apparatus as described above with reference to FIGS. 1 through 10, and thus, detailed descriptions thereof will be omitted.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An audio signal output apparatus comprising:
an audio signal input unit which receives an audio signal;
a digital signal processor (DSP) which estimates an output power corresponding to the received audio signal, and adjusts at least one of a gain value to be applied to the received audio signal and the estimated output power of the received audio signal according to a period for which the estimated output power exceeds a rated maximum output power and a difference between the estimated output power and the rated maximum output power; and
an audio signal output unit which generates, amplifies, and outputs a pulse width modulation (PWM) signal corresponding to the received audio signal.

2. The audio signal output apparatus of claim 1, wherein the DSP adjusts the gain value according to the period and the difference, such that the estimated output power of the received audio signal is adjusted according to the rated maximum output power.

3. The audio signal output apparatus of claim 2, wherein the gain value decreases gradually or linearly during the period for which the estimated output power exceeds the rated maximum output power.

4. The audio signal output apparatus of claim 1, wherein the DSP adjusts the estimated output power of the received audio signal according to the period and the difference, such that the estimated output power of the received audio signal is less than or equal to the rated maximum output power of the audio signal output unit.

5. The audio signal output apparatus of claim 1, wherein the audio signal output unit comprises:
a PWM unit which generates the PWM signal by modulating the pulse width of the received audio signal;
a switching power unit which generates an amplified PWM signal by amplifying a power of the PWM signal; and
a speaker which converts the amplified PWM signal into an audible signal and outputs the audible signal.

6. The audio signal output apparatus of claim 5, wherein the DSP adjusts the estimated output power of the speaker according to the period and the difference, such that the estimated output power of the speaker is less than or equal to the rated maximum output power of the speaker.

7. The audio signal output apparatus of claim 6, wherein the DSP adjusts the estimated output power of the speaker in a low frequency domain, such that the estimated output power of the speaker is less than or equal to the rated maximum output power of the speaker.

8. The audio signal output apparatus of claim 6, wherein the DSP performs an excursion control for lowering an overall output power of the speaker, such that the overall output power of the speaker is less than or equal to the rated maximum output power of the speaker.

9. The audio signal output apparatus of claim 1, further comprising a volume adjusting unit,
wherein the DSP estimates the output power of the audio signal by multiplying a maximum recording level, an audio volume level, and an overall gain value of the audio signal.

10. A method of outputting an audio signal, the method comprising:
receiving an audio signal;
estimating an output power corresponding to the received audio signal;
adjusting at least one of a gain value to be applied to the received audio signal and the estimated output power of the received audio signal according to a period for which the estimated output power exceeds a rated maximum output power and a difference between the estimated output power and the rated maximum output power; and
generating, amplifying, and outputting a pulse width modulation (PWM) signal corresponding to the received audio signal.

11. The method of claim 10, wherein the operation of adjusting at least one of the gain value to be applied to the received audio signal and the estimated output power of the audio signal comprises adjusting the gain value according to the period and the difference, such that the estimated output power of the received audio signal is adjusted according to the rated maximum output power.

12. The method of claim 11, wherein the operation of adjusting at least one of the gain value to be applied to the received audio signal and the estimated output power of the received audio signal comprises reducing the gain value gradually or linearly during the period for which the estimated output power exceeds the rated maximum output power.

13. The method of claim 10, wherein the operation of adjusting at least one of the gain value to be applied to the received audio signal and the estimated output power of the received audio signal comprises adjusting the estimated output power of the audio signal according to the period and the difference, such that the estimated output power of the audio signal is less than or equal to the rated maximum output power of the audio signal output unit.

14. The method of claim 10, wherein the operation of generating, amplifying, and outputting a PWM signal corresponding to the received audio signal comprises:
generating the PWM signal by modulating the pulse width of the received audio signal to which at least one of the adjusted gain value and the adjusted output power is applied;
generating an amplified PWM signal by amplifying a power of the PWM signal; and
converting the amplified PWM signal into an audible signal and outputting the audible signal.

15. The method of claim 14, wherein the operation of adjusting at least one of a gain value to be applied to the received audio signal and the estimated output power of the received audio signal comprises adjusting the estimated output power of the speaker, which is the estimated output power of the audible signal, according to the period and the difference, such that the estimated output power of the speaker is less than or equal to the rated maximum output power of the speaker.

16. The method of claim 10, further comprising adjusting volume of the audio signal to a predetermined volume level,
wherein the operation of estimating the output power corresponding to the received audio signal comprises estimating the output power of the received audio signal by multiplying a maximum recording level, an audio volume level, and an overall gain value of the input audio signal.
